(19) United States
(12) Patent Application Publication
(10) Pub. No.: US 2026/0088260 A1
(43) Pub. Date: Mar. 26, 2026

(54) PYROCHLORE COMPONENT FOR PLASMA PROCESSING CHAMBER

(71) Applicant: Lam Research Corporation, Fremont, CA (US)

(72) Inventors: David Joseph WETZEL, Santa Clara, CA (US); Lin XU, Fremont, CA (US); Lei LIU, Fremont, CA (US); Douglas DETERT, Berkeley, CA (US); Amir A. YASSERI, San Jose, CA (US); John DAUGHERTY, Fremont, CA (US)

(21) Appl. No.: 19/109,741

(22) PCT Filed: Aug. 22, 2023
(86) PCT No.: PCT/US2023/030811

§ 371 Date: Mar. 7, 2025

Related U.S. Application Data
(60) Provisional application No. 63/408,571, filed on Sep. 21, 2022.

(51) Int. Cl. H01J 37/32; H01J 9/20

(52) U.S. Cl. CPC H01J 37/32495; H01J 9/20; H01J 37/32467; H01J 2237/0213

(57) ABSTRACT

A component for use in a plasma processing chamber system is provided. A component body has a plasma facing surface. The plasma facing surface comprises a pyrochlore, comprising at least one of zirconium and hafnium and at least one of lanthanum (La), samarium (Sm), yttrium (Y), erbium (Er), cerium (Ce), gadolinium (Gd), ytterbium (Yb), and neodymium (Nd).

### CROSS-REFERENCE TO RELATED APPLICATION

This application claims the benefit of priority of U.S. Application No. 63/408,571, filed Sep. 21, 2022, which is incorporated herein by reference for all purposes.

### BACKGROUND

The background description provided here is for the purpose of generally presenting the context of the disclosure. The information described in this background section, as well as aspects of the description that may not otherwise qualify as prior art at the time of filing, are neither expressly nor impliedly admitted as prior art against the present disclosure.

The present disclosure generally relates to the manufacturing of semiconductor devices. More specifically, the disclosure relates to plasma chamber components used in manufacturing semiconductor devices.

During semiconductor wafer processing, plasma processing chambers are used to process semiconductor devices. Plasma processing chambers are subjected to plasmas. The plasmas may degrade the component. Coatings may be placed over plasma facing surfaces of components of plasma processing chambers to protect the surfaces.

Some of the coatings may be applied using a plasma spray. One type of coating that may be used is aluminum oxide or alumina (Al₂O₃). It has been found that alumina does not provide enough etch resistance. Another type of coating that might be used is yttrium oxide or yttria (Y₂O₃). It has been found that high purity yttria coatings are expensive to manufacture due to material cost and/or processing costs. Although yttria is more sputter resistant than alumina, yttria is more susceptible to spontaneous fluorination reaction or conversion process than alumina. This fluorine reaction or conversion process may be undesirable and lead to deleterious behavior.

### SUMMARY

To achieve the foregoing and in accordance with the purpose of the present disclosure, a component for use in a plasma processing chamber system is provided. A component body has a plasma facing surface. The plasma facing surface comprises a pyrochlore, comprising at least one of zirconium and hafnium and at least one of lanthanum (La), samarium (Sm), yttrium (Y), erbium (Er), cerium (Ce), gadolinium (Gd), ytterbium (Yb), and neodymium (Nd).

In another manifestation, a method for forming a component for use in a plasma processing chamber system is provided. A component body is provided with a plasma facing surface. The plasma phasing surface comprises a pyrochlore comprising at least one of zirconium (Zr) and hafnium (Hf) and at least one of lanthanum (La), samarium (Sm), yttrium (Y), erbium (Er), cerium (Ce), gadolinium (Gd), ytterbium (Yb), neodymium (Nd).

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart of an embodiment.

FIGS. 2A-B are schematic views of a component processed according to an embodiment.

FIG. 3 is a schematic view of a plasma processing chamber that may be used in an embodiment.

In the drawings, like reference numerals are sometimes used to designate like structural elements. It should also be appreciated that the depictions in the figures are diagrammatic and not to scale.

### DETAILED DESCRIPTION

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well-known process steps and/or structures have not been described in detail in order to not unnecessarily obscure the present disclosure.

In the manufacturing of semiconductor devices, a plasma processing chamber may be used. The plasma processing chamber may have various components that are exposed to plasma during plasma processing. Such components may be aluminum to provide electrical and thermal characteristics that are useful in maintaining the plasma. Aluminum also allows a reduction in weight and cost. Other components may have a dielectric body. Such components may be made of alumina. Ceramic alumina may be used for items such as dielectric inductive power windows or gas injectors.

Such components may be chemically etched by fluorine containing plasma, oxygen containing plasma, or chlorine containing plasma. In addition, the components may be chemically converted or reacted, resulting in surface or bulk changes in plasma exposed areas of the component. The erosion from sputtering may change the shape of the component disrupting the uniformity of the plasma process or may generate particles that become contaminants. A coating may be placed on a plasma facing surface of the aluminum to provide protection from erosion.

Alumina is used as a protective coating. Alumina has some plasma etch resistance. More etch-resistant coatings would provide additional protection to such plasma chamber components. Coatings such as yttria and yttrium aluminum oxide are also used as coatings in some plasma processing chambers. Yttria is more resistant to sputtering than alumina. However, such yttria coatings do not meet the particle requirements at next-generation nodes. Instead, when exposed to fluorine containing plasma, fluorine is absorbed into the yttria coating, so that the yttria coating is fluorinated converting yttria (Y₂O₃) into yttrium fluoride (YF₃) or various forms of YₓO_{y}F_{z} compounds that may be stable or metastable. These compounds create lattice and crystal defects with various intrinsic property defects, resulting in particles that dislodge from the yttria coating and become contaminants. The particles make it more difficult to meet requirements for reduced contaminants. In addition, due to the preferred fluorine conversion reaction of yttria, as an example, some thermal spray yttria coatings may take an undesirably long period of time to reach a chemical steady state when exposed to a fluorine containing plasma environment.

Various embodiments provide a component with a plasma facing surface comprising a pyrochlore. A pyrochlore is a mineral with a general formula of A₂B₂O₇, where A and B are 3+ and 4+ metal cations, respectively. Pyrochlore materials are crystalline but accommodate considerable variation in their crystalline structure and stoichiometry. In some embodiments, there may be up to 10% excess A or B site cations. In some embodiments, the pyrochlore comprises at least one of zirconium and hafnium and at least one of lanthanum (La), samarium (Sm), yttrium (Y), erbium (Er), cerium (Ce), gadolinium (Gd), ytterbium (Yb), and neodymium (Nd). In some embodiments, the pyrochlore comprises at least one of zirconium and hafnium and at least one of La, Ce, and Gd. In some embodiments, the pyrochlore consists essentially of zirconium and La. In some embodiments, the pyrochlore is formed from a material that does not form a volatile halide and is resistant to surface damage from ion bombardment.

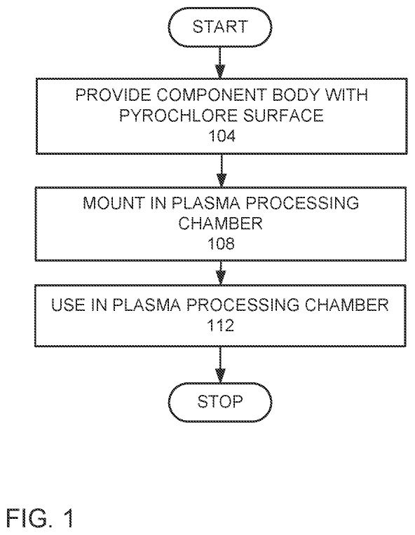

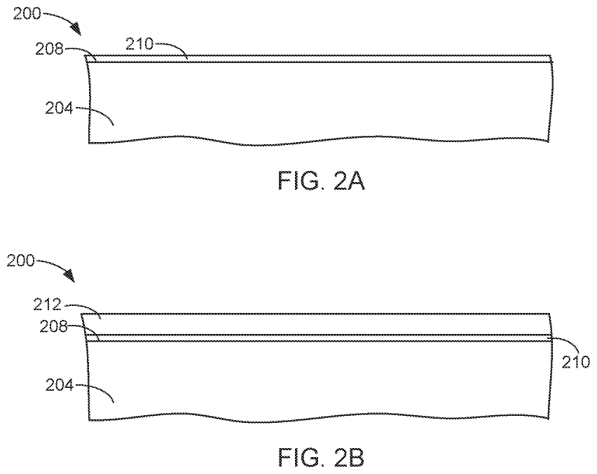

To facilitate understanding, FIG. 1 is a high level flow chart of a process used in an embodiment. A component body is provided (step 104). FIG. 2A is a schematic cross-sectional view of part of a component body 204 of a component 200 that is used in an embodiment. In this example, the component 200 is a ceramic alumina dielectric inductive power window. The component body 204 has a surface 208. In this embodiment, the surface 208 is a plasma facing surface. A plasma facing surface is a surface that will face toward a plasma when the component body 204 is used in a plasma processing chamber. In this embodiment, a layer 210 is formed over the plasma facing surface. In some embodiments, one or more layers may be over the plasma facing surface. In other embodiments, there is not any layer over the plasma facing surface.

Next, the surface 208 and the layer 210 are coated by a pyrochlore coating 212. The pyrochlore coating 212 may be deposited on the surface by one or more of aerosol deposition (AD), atomic layer deposition (ALD), chemical vapor deposition (CVD), physical vapor deposition (PVD), and thermal spraying. In some embodiments, the thermal spraying may be at least one of a suspension plasma spraying, a vacuum plasma spray, a high velocity oxygen fuel spray, and an atmospheric plasma spraying. In some embodiments, a spray powder may be provided by forming a bulk pyrochlore and grinding the bulk pyrochlore into a powder. In some embodiments, the spray powder is formed by component powders of a pyrochlore. For example, if a pyrochlore coating 212 is formed from lanthanum zirconium oxide (LZO), which may have the formula of La₂Zr₂O₇, then the spray powder may comprise lanthanum oxide powder mixed with zirconium oxide, also known as zirconium dioxide, powder. In some embodiments, the pyrochlore coating 212 has a thickness in the range of 100 nm to 300 microns. The plasma facing surface of the pyrochlore coating 212 is the plasma facing surface of the component 200.

In some embodiments, the component body 204 comprises one or more of an electrically conductive metal or ceramic. The electrically conductive metal may comprise one or more of aluminum or a refractory metal. In some embodiments, the refractory metal may comprise one or more of stainless steel, titanium, or nickel alloys. In some embodiments, the nickel alloy is at least 50% Ni by weight. In some embodiments, the component body 204 is a refractory metal if the process of depositing the coating causes the component body 204 to be heated to a temperature of at least 200° C. for a period of at least 10 hours. In some embodiments, the component body 204 comprises aluminum. The aluminum component body may be of an aluminum alloy, such as aluminum 6061. Such an aluminum alloy is at least 95% pure aluminum by weight. In some embodiments, the layer 210 may be one or more layers of an anodization layer or other layers. In other embodiments, there is not any layer and the pyrochlore coating 212 is directly on the surface 208. In some embodiments, the component body 204 comprises a ceramic dielectric material, such as alumina. In some embodiments, coatings may be produced using ceramic powders by a variety of methods known in the art. These methods include thermal spray (plasma, HYO F, detonation gun, etc.), electron beam physical vapor deposition (EBPVD), laser cladding, and plasma transferred arc. If the coating technique used is electronic beam physical vapor deposition (EB-CVD) the ceramic target used could be the pyrochlore—e.g. lanthanum oxide (powder or bulk).

In some embodiments, the pyrochlore coating is patterned. In some embodiments, the patterning is provided by masking a surface of the component body 204 before applying the coating.

In some embodiments, the bulk component body 204 comprises a pyrochlore. In such embodiments, the layer 210 and pyrochlore coating 212 are not needed, since the plasma facing surface is a pyrochlore plasma facing surface. In some embodiments, the bulk component body 204 is formed by sintering. In some embodiments, the component body 204 is formed by spark plasma sintering. In some embodiments, the ceramic powder may be provided by forming a bulk pyrochlore and forming the bulk pyrochlore into a powder. In some embodiments, the ceramic powder is formed by component powders of a pyrochlore. For example, if a component body is formed from LZO, then the ceramic powder may comprise lanthanum oxide powder mixed with zirconium oxide powder.

In some embodiments, the bulk component body 204 comprises a plurality of ceramic layers laminated together to form a ceramic laminate where at least one surface of the bulk component body is a pyrochlore. In some embodiments, the ceramic laminate forming the bulk component body 204 may be formed by a sintering process, such as spark plasma sintering. In an example, a first ceramic powder may be placed in a mold. The first ceramic powder may fill more than 90% of the mold. A layer of a second ceramic powder is placed over the first ceramic powder in the mold. The second ceramic powder may fill less than 10% of the mold. The second ceramic power is a pyrochlore forming powder. In some embodiments, the second ceramic powder may be provided by forming a bulk pyrochlore and forming the bulk pyrochlore into a powder. In some embodiments, the second ceramic powder is formed by component powders of a pyrochlore. For example, if the second ceramic powder is used to form LZO, then the ceramic powder may comprise lanthanum oxide powder mixed with zirconium oxide powder. In some embodiments, the first ceramic powder does not form a pyrochlore. For example, the first ceramic powder may be aluminum oxide to form an aluminum oxide ceramic part. In some embodiments, the resulting component comprises a ceramic component body of the first ceramic powder and a protective pyrochlore layer on a surface of the ceramic component body. In some embodiments, a transition zone of a mixture of the first ceramic powder and the second ceramic powder is between the ceramic component body of the first ceramic powder and the pyrochlore layer. In some embodiments, the ceramic component body may further comprise additional ceramic and transition layers when additional layers of different ceramic powders are provided.

The component body 204 is mounted in a plasma processing chamber (step 108). In this example, the component body 204 is mounted in the plasma processing chamber as a dielectric inductive power window. The plasma processing chamber is used to process a substrate (step 112), where a plasma is created within the chamber to process a substrate, such as etching the substrate, and the pyrochlore surface is exposed to the plasma. The pyrochlore provides increased etch resistance to protect the surface 208 of the component body 204.

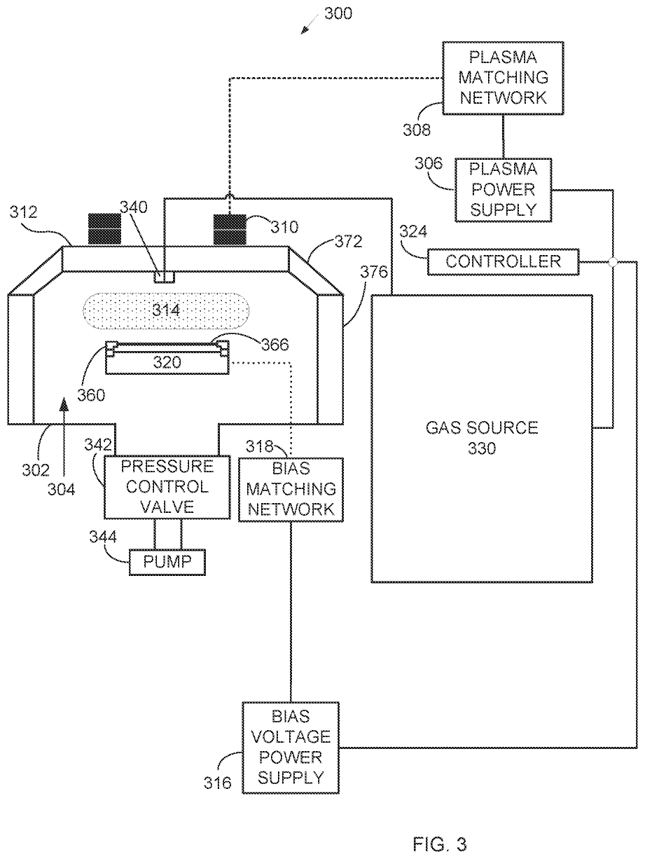

FIG. 3 schematically illustrates an example of a plasma processing chamber system 300 that may be used in an embodiment. The plasma processing chamber system 300 includes a plasma reactor 302 having a plasma processing confinement chamber 304 therein. A plasma power supply 306, tuned by a plasma matching network 308, supplies power to a transformer coupled plasma (TCP) coil 310 located near a dielectric inductive power window 312 to create a plasma 314 in the plasma processing confinement chamber 304 by providing an inductively coupled power. A pinnacle 372 extends from a chamber wall 376 of the plasma processing confinement chamber 304 to the dielectric inductive power window 312 forming a pinnacle ring. The pinnacle 372 is angled with respect to the chamber wall 376 and the dielectric inductive power window 312, such that the interior angle between the pinnacle 372 and the chamber wall 376 and the interior angle between the pinnacle 372 and the dielectric inductive power window 312 are each greater than 90° and less than 180°. The pinnacle 372 provides an angled ring near the top of the plasma processing confinement chamber 304, as shown. The pinnacle 372 is more generically called a chamber liner. The TCP coil (upper power source) 310 may be configured to produce a uniform diffusion profile within the plasma processing confinement chamber 304. For example, the TCP coil 310 may be configured to generate a toroidal power distribution in the plasma 314. The dielectric inductive power window 312 is provided to separate the TCP coil 310 from the plasma processing confinement chamber 304 while allowing energy to pass from the TCP coil 310 to the plasma processing confinement chamber 304. A wafer bias voltage power supply 316 tuned by a bias matching network 318 provides power to an electrode 320 to set the bias voltage on the substrate 366. The substrate 366 is supported by the electrode 320. A controller 324 controls the plasma power supply 306 and the wafer bias voltage power supply 316.

The plasma power supply 306 and the wafer bias voltage power supply 316 may be configured to operate at specific radio frequencies such as for example, 13.56 megahertz (MHz), 27 MHz, 2 MHz, 60 MHz, 400 kilohertz (kHz), 2.54 gigahertz (GHz), or combinations thereof. Plasma power supply 306 and wafer bias voltage power supply 316 may be appropriately sized to supply a range of powers in order to achieve the desired process performance. For example, in one embodiment, the plasma power supply 306 may supply the power in a range of 50 to 5000 Watts, and the wafer bias voltage power supply 316 may supply a bias voltage in a range of 20 to 2000 volts (V). In addition, the TCP coil 310 and/or the electrode 320 may be comprised of two or more sub-coils or sub-electrodes. The sub-coils or sub-electrodes may be powered by a single power supply or powered by multiple power supplies.

As shown in FIG. 3, the plasma processing chamber system 300 further includes a gas source/gas supply mechanism 330. The gas source 330 is in fluid connection with plasma processing confinement chamber 304 through a gas inlet, such as a gas injector 340. The gas injector 340 may be located in any advantageous location in the plasma processing confinement chamber 304 and may take any form for injecting gas. Preferably, however, the gas inlet may be configured to produce a “tunable” gas injection profile. The tunable gas injection profile allows independent adjustment of the respective flow of the gases to multiple zones in the plasma process confinement chamber 304. More preferably, the gas injector is mounted to the dielectric inductive power window 312. The gas injector may be mounted on, mounted in, or form part of the power window. The process gases and by-products are removed from the plasma process confinement chamber 304 via a pressure control valve 342 and a pump 344. The pressure control valve 342 and pump 344 also serve to maintain a particular pressure within the plasma processing confinement chamber 304. The pressure control valve 342 can maintain a pressure of less than 1 torr during processing. An edge ring 360 is placed around the substrate 366. The gas source/gas supply mechanism 330 is controlled by the controller 324. A Kiyo by Lam Research Corp. of Fremont, CA, may be used to practice an embodiment.

In various embodiments, the component may be other parts of a plasma processing chamber, such as confinement rings, edge rings, the electrostatic chuck, a gas injector, ground rings, chamber liners, such as the pinnacle 372, door liners, dielectric windows, chamber walls, or other components. Other components of other types of plasma processing chambers may be used. For example, plasma exclusion rings on a bevel etch chamber may be coated in an embodiment. In another example, a showerhead of a dielectric processing chamber may be coated. In some embodiments, the chamber may have a dome shape, where the coating coats the dome. In some embodiments, one or more, but not all surfaces of a component body 204 are coated.

In some embodiments, after a coating is deposited, the coating is machined, ground, and/or polished. In an example, the component may have a surface with a complex shape. Because the surface has a complex shape, the thickness of the coating may be nonuniform. Machining, grinding, and/or polishing may be used to provide a more uniform thickness. The uniform thickness may improve process uniformity, control coating stresses to prevent mechanical coating failure, and ensure that the part is able to fit with adjacent components. In an embodiment, a coating with a thickness of about 1500 μm thick was deposited. Machining and grinding reduce the thickness of the coating to a uniform thickness of less than 1000 μm. Polishing using a very fine grit high-hardness abrasive either embedded in a polishing pad or in a slurry may be used to reduce the roughness of the coating so that the plasma facing surface of the chamber has a uniform roughness. In some embodiments, the roughness is less than 5 μm Ra. Such a roughness may be achieved by spraying or with basic machining and/or grinding. In some embodiments, the roughness is less than 1.5 μm Ra. In some embodiments, the roughness of between 0.5 μm and 1.5 μm Ra. In some embodiments, the roughness of between 0.005 μm and 0.5 μm Ra.

While this disclosure has been described in terms of several preferred embodiments, there are alterations, permutations, modifications, and various substitute equivalents, which fall within the scope of this disclosure. It should also be noted that there are many alternative ways of implementing the methods and apparatuses of the present disclosure. It is therefore intended that the following appended claims be interpreted as including all such alterations, permutations, and various substitute equivalents as fall within the true spirit and scope of the present disclosure. As used herein, the phrase “A, B, or C” should be construed to mean a logical (“A OR B OR C”), using a non-exclusive logical “OR,” and should not be construed to mean ‘only one of A or B or C. Each step within a process may be an optional step and is not required. Different embodiments may have one or more steps removed or may provide steps in a different order. In addition, various embodiments may provide different steps simultaneously instead of sequentially.

What is claimed is:

1. A component for use in a plasma processing chamber system, comprising a component body with a plasma facing surface, wherein the plasma facing surface comprises a pyrochlore, comprising:
at least one of zirconium and hafnium; and
at least one of lanthanum (La), samarium (Sm), yttrium (Y), erbium (Er), cerium (Ce), gadolinium (Gd), ytterbium (Yb), and neodymium (Nd).

2. The component, as recited in claim 1, wherein the pyrochlore comprises zirconium and La.

3. The component, as recited in claim 1, wherein the component body comprises the pyrochlore forming a bulk component body.

4. The component, as recited in claim 1, wherein the plasma facing surface comprises a coating on a surface of the component body.

5. The component, as recited in claim 4, wherein the component body comprises an electrically conductive metal.

6. The component, as recited in claim 5, wherein the electrically conductive metal is a refractory metal.

7. The component, as recited in claim 4, wherein the component body comprises a ceramic.

8. The component, as recited in claim 4, wherein the coating has a thickness in a range of 100 nm to 300 microns.

9. The component, as recited in claim 1, wherein the component forms at least one of a gas injector, chamber liner, chamber wall, and dielectric window.

10. The component, as recited in claim 1, wherein the component body comprises a ceramic laminate comprising a ceramic component body of a first ceramic powder and a pyrochlore layer on a surface of the component body.

11. The component, as recited in claim 10, wherein the ceramic component body of the first ceramic powder is not a pyrochlore.

12. A method for forming a component for use in a plasma processing chamber system, the method comprising providing a component body with a plasma facing surface, wherein the plasma phasing surface comprises a pyrochlore comprising at least one of zirconium (Zr) and hafnium (Hf) and at least one of lanthanum (La), samarium (Sm), yttrium (Y), erbium (Er), cerium (Ce), gadolinium (Gd), ytterbium (Yb), neodymium (Nd).

13. The method, as recited in claim 12, the forming of the component body comprises spark plasma sintering a ceramic powder.

14. The method, as recited in claim 12, wherein the forming the component body comprises:
providing a bulk component body; and
forming a pyrochlore coating on a surface of the bulk component body.

15. The method, as recited in claim 14, wherein the forming the pyrochlore coating is by at least one of atomic layer deposition, aerosol deposition, thermal spraying, PVD, and CVD.

16. The method, as recited in claim 12, wherein the pyrochlore comprises zirconium and La.

17. A product made by the method as recited in claim 12.
